(19) United States
(12) Patent Application Publication
(10) Pub. No.: US 2014/0352780 A1
(43) Pub. Date: Dec. 4, 2014

(54) SOLAR CELL, SOLAR CELL MODULE, AND METHOD OF MANUFACTURING SOLAR CELL

(71) Applicant: SANYO ELECTRIC CO., LTD., Osaka (JP)

(72) Inventor: Takeshi NISHIWAKI, Kishiwada (JP)

(21) Appl. No.: 14/459,369

(22) Filed: Aug. 14, 2014

Related U.S. Application Data
(63) Continuation of application No. PCT/JP2012/057481, filed on Mar. 23, 2012.

(51) Int. Cl. H01L 31/0224; H01L 31/0236; H01L 31/048

(52) U.S. Cl. CPC H01L 31/022433; H01L 31/048; H01L 31/02363
USPC 136/256; 438/98

(57) ABSTRACT

A solar cell includes a photoelectric conversion body having principal surface with rugged structures and an electrode on the principal surface. The electrode includes first conductive materials, second conductive materials and resin. The second conductive materials are flat-shaped so that an aspect ratio of the second conductive materials, which is a ratio of a major axis diameters to their average thickness (the major axis diameter divided by the average thickness), is larger than that of the first conductive materials. In the electrode, a volume fraction of the second conductive materials is larger than that of the first conductive materials. The rugged structures include rugged structures which are larger than an average particle size of the first conductive materials, but smaller than an average major axis diameter of the second conductive materials.

### CROSS REFERENCE TO RELATED APPLICATIONS

This application is a continuation application of International Application No. PCT/JP2012/057481, filed on Mar. 23, 2012, entitled “SOLAR CELL, SOLAR CELL MODULE, AND SOLAR CELL MANUFACTURING METHOD”, the entire contents of which are incorporated herein by reference.

### BACKGROUND

The invention relates to a solar cell, a solar cell module, and a method of manufacturing a solar cell.

Patent Document 1 relates to formation of an electrode for a solar cell, and describes the formation of the electrode by applying conductive paste to a surface of a photoelectric conversion body which has a texture structure.

Patent Document 1: Japanese Patent Application Publication No. 2002-76398

### SUMMARY OF THE INVENTION

There has been a demand for improvement in accuracy of the shape of an electrode for a solar cell.

An aspect of the invention provides a solar cell including an electrode with high shape accuracy.

A solar cell of an embodiment includes a photoelectric conversion body and an electrode. The photoelectric conversion body has a principal surface provided with rugged structures. The electrode is disposed on the principal surface. The electrode includes first conductive materials, second conductive materials and resin. The second conductive materials are flat-shaped so that an aspect ratio of the second conductive materials, which is a ratio of a major axis diameters to their average thickness (the major axis diameter divided by the average thickness), is larger than that of the first conductive materials. In the electrode, a volume fraction of the second conductive materials is larger than that of the first conductive materials. The rugged structures include rugged structures which are larger than an average particle size of the first conductive materials, but smaller than an average major axis diameter of the second conductive materials.

A solar cell module of an embodiment includes solar cells, a first protection member, a second protection member and a sealing material. The first protection member is disposed on one side of the solar cells. The second protection member is disposed on the opposite side of the solar cells. The sealing material is disposed between the first and second protection members. The sealing material seals the solar cells. Each solar cell includes a photoelectric conversion body and an electrode. The photoelectric conversion body has a principal surface provided with rugged structures. The electrode is disposed on the principal surface. The electrode includes first conductive materials, second conductive materials and resin. The second conductive materials are flat-shaped so that an aspect ratio of the second conductive materials, which is a ratio of a major axis diameter to an average thickness (the major axis diameter divided by the average thickness), is larger than that of the first conductive materials. In the electrode, a volume fraction of the second conductive materials is larger than that of the first conductive materials. The rugged structures include rugged structures which are larger than the average particle size of the first conductive materials, but smaller than the average major axis diameter of the second conductive materials.

In a method of manufacturing a solar cell of an embodiment, paste is prepared which includes first conductive materials, second conductive materials and resin. Here, the second conductive materials are flat-shaped so that an aspect ratio of the second conductive materials, which is a ratio of a major axis diameter to an average thickness (the major axis diameter divided by the average thickness) is larger than that of the first conductive materials. In the paste, a volume fraction of the second conductive materials is larger than that of the first conductive materials. The paste is applied to a principal surface of a photoelectric conversion body which is provided with rugged structures larger than the average particle size of the first conductive materials, but smaller than the average major axis diameter of the second conductive materials. Thereby, an electrode including the first conductive materials, the second conductive materials and the resin is formed.

The embodiments above provide a solar cell including an electrode with high shape accuracy.

### BRIEF DESCRIPTION OF THE DRAWINGS

FIG. 1 is a schematic cross-sectional view of a solar cell module of an embodiment.

FIG. 2 is a schematic plan view of a solar cell of the embodiment.

FIG. 3 is a schematic rear view of the solar cell of the embodiment.

FIG. 4 is a schematic cross-sectional view of the solar cell taken along the IV-IV line of FIG. 2.

### EMBODIMENTS

Hereinafter, examples of preferred embodiments are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated schematically, and the dimensional ratio and the like of objects depicted in the drawings are different from those of actual objects in some cases. The dimensional ratio and the like of objects are also different among the drawings in some cases. The specific dimensional ratio and the like of objects should be determined with the following description taken into consideration.

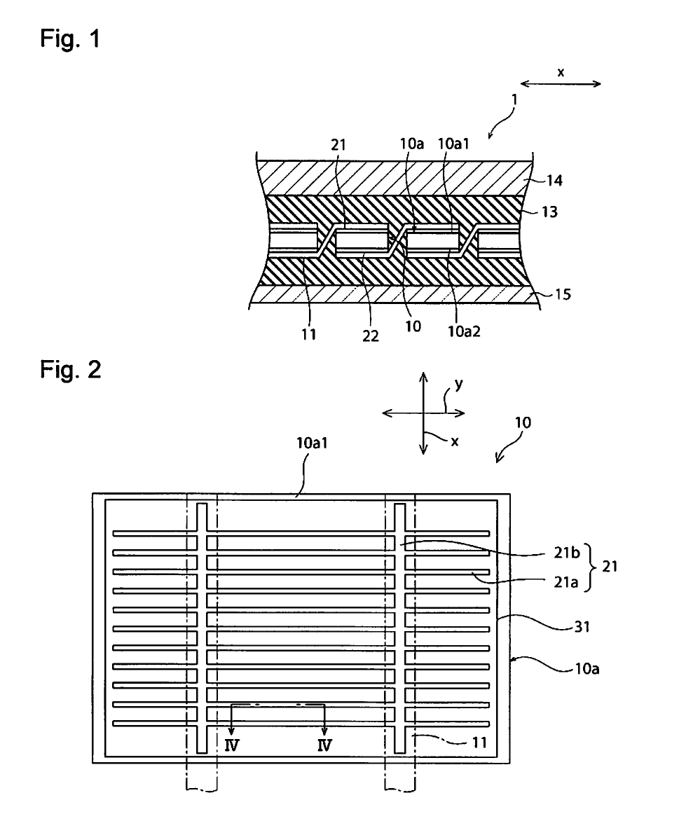

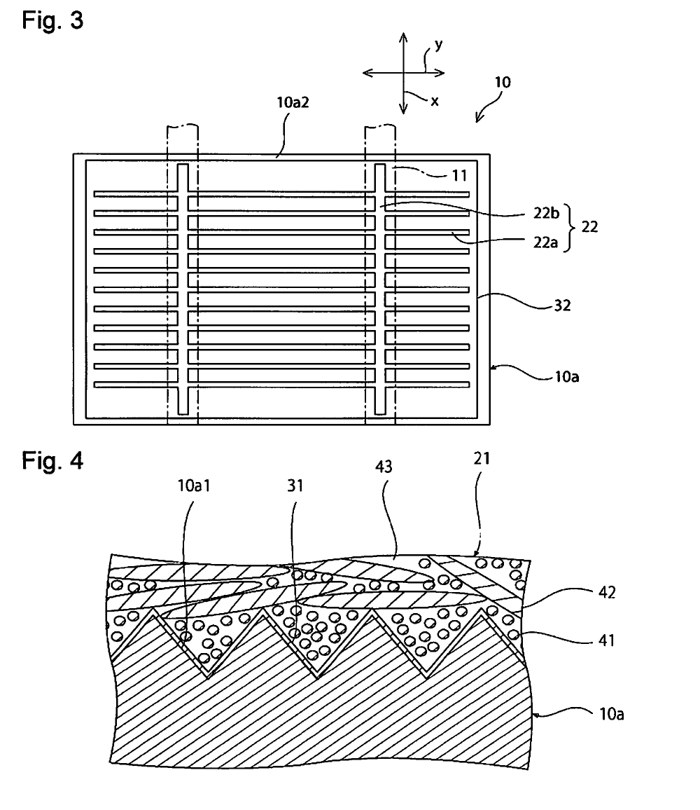

As illustrated in FIG. 1, solar cell module 1 includes a plurality of solar cells 10 electrically connected by wiring materials 11. Otherwise, solar cell module may include one solar cell only.

Solar cell 10 includes photoelectric conversion body 10a. Photoelectric conversion body 10a is configured to generate carriers such as electrons or holes upon receipt of light. Photoelectric conversion body 10a maybe configured to generate carriers only when receiving light by use of principal surface 10a1. Otherwise, photoelectric conversion body 10a may be configured to generate power not only when receiving light by use of principal surface 10a1, but also when receiving light by use of principal surface 10a2. Photoelectric conversion body 10a may include, for example, a substrate made of a semiconductor material. To put it concretely, photoelectric conversion body 10a may include, for example, a crystalline silicon plate, and p- and n-type semiconductor layers which are disposed on the crystalline silicone plate. Otherwise, photoelectric conversion body 10a maybe made of a crystalline silicon plate which includes p- and n-type dopant diffused regions exposed to the surface.

As illustrated in FIG. 4, rugged structures, which are termed as texture structures, are provided to at least one of principal surfaces 10a1, 10a2 of photoelectric conversion body 10a. To put it concretely, the rugged structures termed as texture structures are provided to both principal surfaces 10a1, 10a2. In this respect, the “texture structure” is a rugged structure which is formed to inhibit surface reflection, and to increase the amount of light absorbed by the photoelectric conversion body. A concrete example of the texture structure is a pyramid-shaped (quadrangular pyramid-shaped, truncated quadrangular pyramid-shaped) rugged structure which is obtained by anisotropically etching a surface of a single-crystalline silicon substrate having the (100) plane.

The size of each texture structure (distance between adjacent top portions) is preferably in a range of about 1 μm to 20 μm, for example, or more preferably in a range of 3 μm to 10 μm. Nevertheless, the sizes of a plurality of protrusions forming the texture structure are not necessarily the same. A plurality of protrusions forming the texture structure may include protrusions whose sizes fall outside the preferable range.

First and second electrode 21, 22 are disposed on photoelectric conversion body 10a. Specifically, first electrode 21 is disposed on principal surface 10a1, and second electrode 22 is disposed on principal surface 10a2. One of first and second electrodes 21, 22 is an electrode configured to collect majority carriers, and the other electrode is an electrode configured to collect minority carriers.

First electrode 21 includes a plurality of finger portions 21a and bus bar portions 21b. The plurality of finger portions 21a are disposed at intervals in an X-axis direction. The plurality of finger portions 21a are electrically connected to bus bar portions 21b. First electrode 21 is electrically connected to wiring material 11 mainly through bus bar portion 21b.

Second electrode 22 includes a plurality of finger portions 22a and bus bar portions 22b. The plurality of finger portions 22a are disposed at intervals in the X-axis direction. The plurality of finger portions 22a are electrically connected to bus bar portions 22b. Second electrode 22 is electrically connected to wiring material 11 mainly through bus bar portion 22b.

Transparent conductive oxide layer 31 is disposed between first electrode 21 and principal surface 10a1. Transparent conductive oxide layer 31 is disposed covering virtually all principal surface 10a1. Transparent conductive oxide layer 32 is disposed between second electrode 22 and principal surface 10a2. Transparent conductive oxide layer 32 is disposed covering virtually all principal surface 10a2. Transparent conductive oxide layers 31, 32 each may be made of indium tin oxide (ITO), for example.

As illustrated in 4, first electrode 21 include first conductive materials 41, second conductive materials 42 and resin 43. First conductive material 41 may be made of a plurality of particle aggregates. In a case where the particles constituting first conductive material 41 do not form an aggregate, then first conductive material 41 is formed from one particle. In this case, therefore, the particle size of first conductive material 41 is a primary particle size. In a case where particles constituting first conductive material 41 form aggregates, first conductive material 41 is formed from an aggregate containing a plurality of particles. In this case, therefore, the particle size of first conductive material 41 is a secondary particle size. The particle size of the first conductive material can be measured by a laser diffraction/scattering method.

Second conductive materials 42 are flat-shaped. An aspect ratio of second conductive materials 42, which is a ratio of a major axis diameter to an average thickness (the major axis diameter divided by the average thickness), is larger than that of first conductive materials 41. The aspect ratio of second conductive materials 42 is preferably three or more times as large, or more preferably five or more times as large as the aspect ratio of first conductive materials 41. To put it concretely, the aspect ratio of first conductive materials 41 is preferably in a range of 1 to 3, or more preferably in a range of 1 to 2.

A volume fraction of second conductive materials 42 is larger than that of first conductive materials 41. The volume fraction of second conductive materials 42 is preferably 1.2 or more times, or more preferably 1.3 or more times that of first conductive materials 41. To put it concretely, the volume fraction of first conductive materials 41 in each of first and second electrodes 21, 22 is preferably in a range of 25 volume percent to 45 volume percent, or more preferably in a range of 30 volume percent to 40 volume percent. The volume fraction of second conductive materials 42 in each of first and second electrodes 21, 22 is preferably in a range of 55 volume percent to 75 volume percent, or more preferably in a range of 60 volume percent to 70 volume percent.

The average particle size of first conductive materials 41 is preferably in a range of 0.5 μm to 3 μm, or more preferably in a range of 0.5 μm to 2 μm. The average major axis diameter of second conductive materials 42 is preferably in a range of 3 μm to 10 μm, or more preferably in a range of 5 μm to 8 μm. The average thickness of second conductive materials 42 is preferably in a range of 0.1 μm to 1.5 μm, or more preferably in a range of 0.3 μm to 1 μm. The average major axis diameter and average thickness of second conductive materials 42 can be measured by SEM observation.

First and second conductive materials 41, 42 each may be made of an appropriate conductive material. First and second conductive materials 41, 42 each may be made of at least one metal selected from a group consisting of Ag, Cu, Au, Pt, Al, Ni and Sn, for example. It is desirable that the essential component of first conductive materials 41 and the essential component of second conductive materials 42 be the same. For example, it is desirable that first and second conductive materials 41, 42 both contain Ag or Au as an essential component.

As illustrated in FIG. 1, first protection member 14 is disposed on one side of solar cells 10. Second protection member 15 is disposed on the opposite side of solar cells 10. Sealing material 13 is disposed between first and second protection members 14, 15. Sealing material 13 seals solar cells 10. At least one of first and second protection members 14, 15 includes a resin sheet. To put it concretely, at least one of first and second protection members 14, 15 includes a resin sheet which does not include a barrier layer such as a metal layer or an inorganic oxide layer. To put it more concretely, first protection member 14 placed on a light receiving surface side of solar cells 10 is made of a glass plate, a ceramic plate or a resin plate. Second protection member 15 placed on the rear surface side of solar cells 10 includes a resin sheet which does not include a barrier layer such as a metal layer or an inorganic oxide layer. Sealing material 13 may be made of a crosslinked resin such as ethylene-vinyl acetate copolymer, or a non-crosslinked resin such as polyolefin.

First and second electrodes 21, 22 can be formed in the following procedure, for example. Specifically, Prepared is conductive paste including first and second conductive materials 41, 42 and resin 43. In this conductive paste, the volume fraction of second conductive materials 42 is larger than that of first conductive materials 41. Thereafter, the conductive paste is applied onto photoelectric conversion body 10a, and resin 43 is cured. Thereby, first and second electrodes 21, 22 can be formed.

For example, if the particle sizes of the conductive materials included in the conductive paste are smaller than pitches of the rugged structures, the conductive materials, together with the resin in the applied conductive paste, are easily spread along recessed portions in the rugged structures. For this reason, it is difficult to apply the conductive paste with high shape accuracy. This makes it difficult to form the electrodes with high shape accuracy.

Here, second conductive materials 42 are flat-shaped. The rugged structures include rugged structures smaller (narrower in pitch) than the major axis diameters of second conductive materials 42. For this reason, second conductive materials 42 are hard to spread along the recessed portions in the rugged structures. Second conductive materials 42 that are hard to spread are included in the conductive paste by the higher volume fraction than that of the first conductive materials. This makes it possible to obtain electrodes 21, 22 with high shape accuracy.

An increase in viscosity of the conductive paste, for example, makes it possible to inhibit wetting spread of the conductive paste, too. However, it is difficult to apply the conductive paste if the viscosity of the conductive paste is high. As a consequence, the shape accuracy of the obtained electrodes may be degraded if the viscosity of the conductive paste is high. In the case where second conductive materials 42 are flat-shaped while the rugged structures include rugged structures smaller (narrower in pitch) than the major axis diameters of second conductive materials 42, the conductive paste is hard to wettingly spread even though the viscosity of the conductive paste is lower. This makes it possible to obtain electrodes 21, 22 with high shape accuracy.

For example, if the electrodes include only the second conductive materials with the higher aspect ratio, the second conductive materials have difficulty in getting into the rugged structures. As a result, the electric resistance is likely to become higher in the interfaces between the electrodes and the photoelectric conversion body, or in the interfaces between the electrodes and the transparent conductive oxide layers. In solar cell module 1, electrodes 21, 22 each include not only second conductive materials 42 but also first conductive materials 41. The rugged structures include the rugged structures larger than the average particle size of first conductive materials 41. For this reason, the electric resistance is low in the interfaces between electrodes 21, 22 and transparent conductive oxide layers 31, 32. Accordingly, the improved photoelectric conversion efficiency can be realized.

From a viewpoint of a further improving the photoelectric conversion efficiency and obtaining electrodes 21, 22 with higher shape accuracy, it is desirable that more than a half, or more preferably, virtually all of the rugged structures provided to at least one of principal surfaces 10a1, 10a2 of photoelectric conversion body 10a be larger than the average particle size of first conductive materials 41, but smaller than the average major axis diameter of second conductive materials 42. It is desirable that the rugged structures include rugged structures which are three or more times the average particle size of first conductive materials 41, but two or less times the average major axis diameter of second conductive materials 42. More desirably, the rugged structures include the rugged structures which are five or more times the average particle size of first conductive materials 41, but 1.5 or less times the average major axis diameter of second conductive materials 42. It is desirable that more than a half, or more preferably, virtually all of the rugged structures be three or more times the average particle size of first conductive materials 41, but two or less times the average major axis diameter of second conductive materials 42. It is more desirable that more than a half or virtually all of the rugged structures be five or more times the average parcel size of first conductive materials 41, but 1.5 or less times the average major axis diameter of second conductive materials 42.

Meanwhile, if at least any one of first and second protection members 14, 15 includes a resin sheet without including a barrier layer, moisture is highly likely to enter sealing material 13 via such the resin sheet. If the moisture entering sealing material 13 reaches electrodes 21, 22, resin 43 in electrodes 21, 22 deteriorates. As a result, it is more likely that: electric resistance becomes higher in the interfaces between electrodes 21, 22 and transparent conductive oxide layers 31, 32; and the photoelectric conversion efficiency deteriorates. In solar cell module 1, electrodes 21, 22 include flat-shaped second conductive materials 42. For this reason, the number of conductive materials 41, 42 existing in each unit length is small in electrodes 21, 22. As a consequence, the number of spaces between the conductive materials existing in each unit length is small, too. Accordingly, even if the electric resistance rises in resin 43 located in the spaces between the conductive materials, the electric resistance such as contact resistance is less likely to rise in electrodes 21, 22. This makes the output characteristics of solar cell module 1 less likely to become worse. In short, since the volume fraction of flat-shaped second conductive materials 42 having the relatively higher aspect ratio is set larger than that of first conductive materials 41, the moisture resistance of solar cell module 1 can be improved.

### Modified Examples

Each electrode may be disposed directly on the photoelectric conversion body. In other words, the transparent conductive oxide layer does not have to be disposed between each electrode and the photoelectric conversion body. Each electrode may be provided in a planar shape. The solar cell may be a back contact solar cell.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell comprising:
a photoelectric conversion body including a principal surface provided with rugged structures, and
an electrode disposed on the principal surface, and including first conductive materials, second conductive materials and resin, wherein
the second conductive materials are flat-shaped so that an aspect ratio of the second conductive materials that is a ratio of a major axis diameter to an average thickness (the major axis diameter divided by the average thickness) is larger than that of the first conductive materials,
in the electrode, a volume fraction of the second conductive materials is larger than that of the first conductive materials, and
the rugged structures include rugged structures which are larger than an average particle size of the first conductive materials, but smaller than an average major axis diameter of the second conductive materials.

2. The solar cell according to claim 1, wherein in the electrode, the volume fraction of the second conductive materials is 1.2 or more times the volume fraction of the first conductive materials.

3. The solar cell according to claim 1, wherein
the rugged structures include rugged structures which are three or more times the average particle size of the first conductive materials, but are two or more times the average major axis diameter of the second conductive materials.

4. The solar cell according to claim 2, wherein
the rugged structures include rugged structures which are three or more times the average particle size of the first conductive materials, but are two or more times the average major axis diameter of the second conductive materials.

5. The solar cell according to claim 1, wherein
the aspect ratio of the first conductive materials is in a range of 1 to 3, and
the aspect ratio of the second conductive materials is in a range of 5 to 20.

6. The solar cell according to claim 2, wherein
the aspect ratio of the first conductive materials is in a range of 1 to 3, and
the aspect ratio of the second conductive materials is in a range of 5 to 20.

7. The solar cell according to claim 3, wherein
the aspect ratio of the first conductive materials is in a range of 1 to 3, and
the aspect ratio of the second conductive materials is in a range of 5 to 20.

8. The solar cell according to claim 4, wherein
the aspect ratio of the first conductive materials is in a range of 1 to 3, and
the aspect ratio of the second conductive materials is in a range of 5 to 20.

9. The solar cell according to claim 1, wherein
the first conductive materials and the second conductive materials contain the same component as a main component.

10. The solar cell according to claim 2, wherein
the first conductive materials and the second conductive materials contain the same component as a main component.

11. The solar cell according to claim 3, wherein
the first conductive materials and the second conductive materials contain the same component as a main component.

12. The solar cell according to claim 4, wherein
the first conductive materials and the second conductive materials contain the same component as a main component.

13. The solar cell according to claim 5, wherein
the first conductive materials and the second conductive materials contain the same component as a main component.

14. The solar cell according to claim 6, wherein
the first conductive materials and the second conductive materials contain the same component as a main component.

15. The solar cell according to claim 7, wherein
the first conductive materials and the second conductive materials contain the same component as a main component.

16. The solar cell according to claim 8, wherein
the first conductive materials and the second conductive materials contain the same component as a main component.

17. A solar cell module comprising:
a solar cell;
a first protection member disposed on one side of the solar cell;
a second protection member disposed on an opposite side of the solar cell; and
a sealing material disposed between the first protection member and the second protection member, and sealing the solar cell, wherein
the solar cell includes
a photoelectric conversion body including a principal surface provided with rugged structures, and
an electrode disposed on the principal surface, and including first conductive materials, second conductive materials and resin,
the second conductive materials are flat-shaped so that an aspect ratio of the second conductive materials, which is a ratio of a major axis diameter to an average thickness (the major axis diameter divided by the average thickness), is larger than that of the first conductive materials,
in the electrode, a volume fraction of the second conductive materials is larger than that of the first conductive materials, and
the rugged structures include rugged structures which are larger than an average particle size of the first conductive materials, but smaller than an average major axis diameter of the second conductive materials.

18. The solar cell module according to claim 17, wherein
at least one of the first and second protection members includes a resin sheet.

19. A method of manufacturing a solar cell comprising:
preparing paste which includes first conductive materials, second conductive materials and resin, in which the second conductive materials are flat-shaped so that an aspect ratio of the second conductive materials, which is a ratio of a major axis diameter to an average thickness (the major axis diameter divided by the average thickness) is larger than those of the first conductive materials, and in which a volume fraction of the second conductive materials is larger than that of the first conductive materials; and
forming an electrode including the first conductive materials, the second conductive materials and the resin by applying the paste onto a principal surface of a photoelectric conversion body, the principal surface provided with rugged structures which are larger than an average particle size of the first conductive materials, but smaller than an average major axis diameter of the second conductive materials.
